(19) United States
(12) Patent Application Publication
(10) Pub. No.: US 2025/0309570 A1
(43) Pub. Date: Oct. 2, 2025

(54) HYBRID SOCKET INTERCONNECTS

(71) Applicant: Intel Corporation, Santa Clara, CA (US)

(72) Inventors: Karumbu Nathan Meyyappan, Portland, OR (US); Srikant Nekkanty, Chandler, AZ (US)

(73) Assignee: Intel Corporation, Santa Clara, CA (US)

(21) Appl. No.: 18/622,772

(22) Filed: Mar. 29, 2024

(51) Int. Cl. H01R 12/52; H01L 23/498

(52) U.S. Cl. CPC H01R 12/52; H01L 23/49811

(57) ABSTRACT

In one embodiment, an apparatus includes a socket interconnect that implements a liquid metal (LM)-based connection mechanism and another type of connection mechanism, such as a land grid array (LGA)-, pin grid array (PGA)-, or compression mount technology (CMT)-based connection mechanism.

### BACKGROUND

Land grid array (LGA) and liquid metal (LM) interconnect architectures may provide separable and reusable interconnections for integrated circuit devices, e.g., in lieu of traditional solder-based interconnection technologies (e.g., ball grid arrays) that are substantially permanent in their current implementations.

### BRIEF DESCRIPTION OF THE DRAWINGS

FIGS. 1A-1B illustrate an example integrated circuit device assembly that utilizes a hybrid land grid array (LGA)-liquid metal (LM) socket interconnect in accordance with embodiments of the present disclosure.

FIG. 2 illustrates an exploded view of the example hybrid interconnect of FIGS. 1A-1B.

FIGS. 3A-3B illustrate perspective views of the interposer of the example hybrid interconnect of FIGS. 1A-1B.

FIG. 4 illustrates a cross-sectional view of the example hybrid interconnect of FIGS. 1A-1B.

FIG. 5 illustrates an example hybrid socket with varying LM pin dimensions for use with a hybrid LGA-LM interconnect.

FIGS. 6A-6B illustrate an example integrated circuit device assembly that utilizes a hybrid pin grid array (PGA)-liquid metal (LM) socket interconnect in accordance with embodiments of the present disclosure.

FIG. 7 is a top view of a wafer and dies that may be included in a microelectronic assembly, in accordance with any of the embodiments disclosed herein.

FIG. 8 is a cross-sectional side view of an integrated circuit device that may be included in a microelectronic assembly, in accordance with any of the embodiments disclosed herein.

FIG. 9 is a block diagram of an example electrical device that may include a microelectronic assembly, in accordance with any of the embodiments disclosed herein.

### DETAILED DESCRIPTION

Embodiments herein include integrated circuit device assemblies with interconnects that implement liquid metal (LM)-based interconnect technologies and land grid array (LGA)- or pin grid array (PGA)-based interconnect technologies. For example, an LGA-based portion of an interconnect may implement spring-like pins that connect to pads on the backside of an integrated circuit device package, wherein the pins compress under pressure of the package being attached to the socket. The LM-based portion of the interconnect may implement straight pins that are inserted into wells on the backside of the integrated circuit device package that include a LM alloy, e.g., a Gallium (Ga)-based LM alloy. In other embodiments, the LM-based portion may implement small stubs that are in similar size/height as metal pads.

Typical LGA technologies require a significant amount of load to attach a package to the socket, while also having relatively higher resistances than LM-based technologies. This is because LGA technologies typically include pins that function as mechanical springs, and a chosen pin shape/formation for the LGA will have an ideal force/defection range where stable resistance is achieved. Mixing pins with different spring rates is unlikely to help achieve stable contact resistance for the individual springs.

LM-based interconnect technologies, on the other hand, are incredibly compliant and the measured resistance is primarily due to bulk conduction. These interconnects can therefore provide a low insertion force and low contact resistance interface between the package substrate and the socket. For example, LM-based technologies can offer approximately 20% of the resistance of similar LGA-based technologies. However, due to a self-healing cap, the LM-based interconnects require some load to extract the package from the socket. This can be achieved through reaction springs that are added in a retention mechanism of the socket, which would add cost and require additional space to implement.

Embodiments of the present disclosure, however, provide for a hybrid LGA-LM interconnect design where a load to engage/attach a package is lower than typical LGA-only technologies while also requiring little to no separate extraction force. In addition, some embodiments may implement LM interconnect pins of different diameters and/or varying heights, which can help mitigate electrostatic discharge (ESD) risks over current LM-only interconnects that can require expensive capacitor-based solutions to prevent ESD. Moreover, embodiments herein can improve power delivery performance for integrated circuit device packages, since current technologies can require higher pin counts to address higher resistances in the interconnect, which in turn require a larger socket/package size and accordingly higher mechanical loads. For instance, LGA technologies suffer from higher contact resistance, which can be addressed using an LM-based interconnect for power delivery pins in the package. In addition, hybrid interconnects as described herein can provide high speed signaling in both technologies and can address forthcoming high-speed interconnect requirements (e.g., PCI Gen 7+), thus, various aspects of each type of interconnect technology can be drawn from to create a hybrid interconnect that best addresses such requirements. The concepts described herein can also be extended to LM-PGA hybrid interconnects as well.

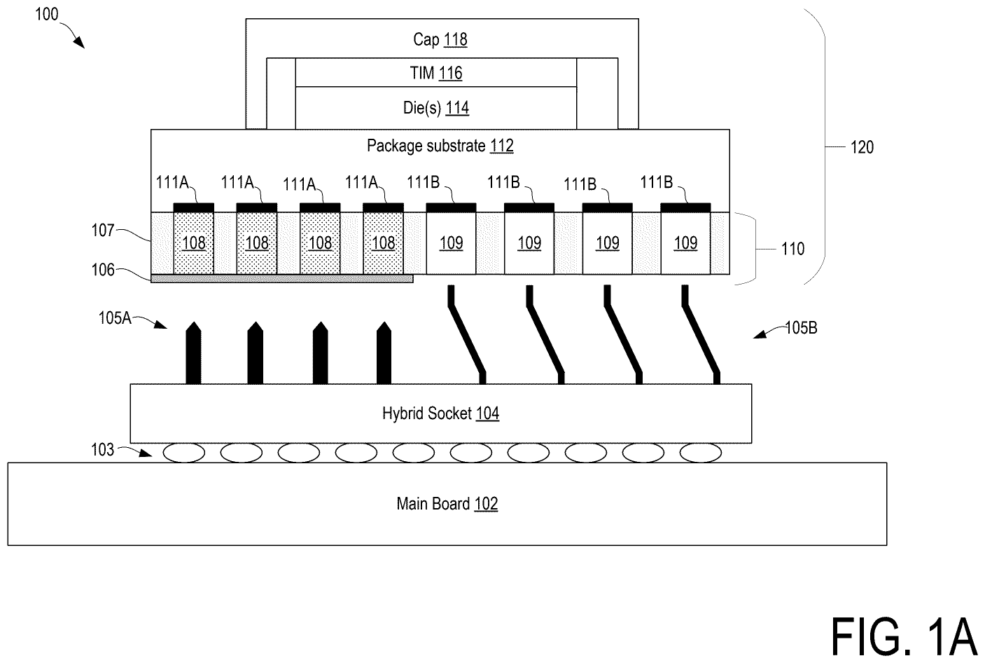

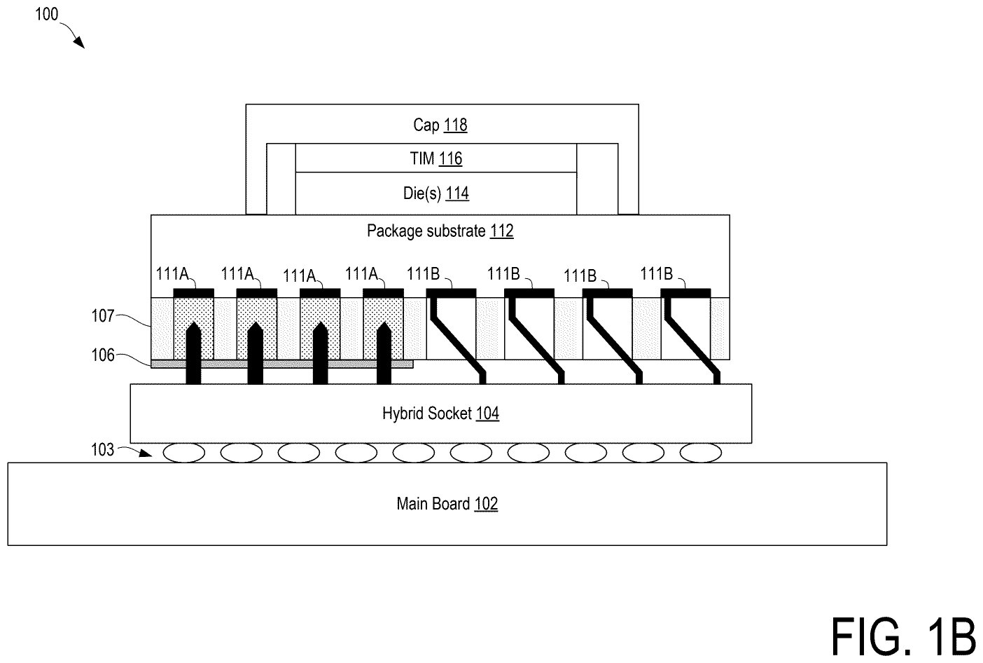

FIGS. 1A-1B illustrate an example integrated circuit device assembly 100 that utilizes a hybrid land grid array (LGA)-liquid metal (LM) socket interconnect in accordance with embodiments of the present disclosure. In the example shown, the assembly 100 includes a main board 102, which may be a motherboard, system board, etc. The main board 102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the main board 102. In other embodiments, the main board 102 may be or include a non-PCB substrate.

The assembly 100 also includes a hybrid socket 104 with a set of LM-compatible pins 105A and a set of LGA-compatible pins 105B. The socket 104 is coupled to the main board 102 via solder bumps 103, and interconnects the pins 105A, 105B on the top side of the socket 104 to the circuitry of the main board 102. The bumps 103 may be formed using Tin or any other suitable solder bump material. In some embodiments, the socket 104 may be coupled to the main board 102 via other mechanisms.

The LM-compatible pins 105A include sharp ends, and enable an electrical connection between the main board 102 and the die(s) 114 (through the LM in wells/openings 108, pads 111, and conductive paths in the package substrate 112). The sharp ends of the pins 105A may pierce the barrier 106 of the interposer 110 of the package 120, causing the pins 105A to be in physical contact with the LM inside the openings 108, and to thus be in electrical contact with the metal pads 111A of the package substrate 112.

The LGA-compatible pins 105B function as springs that flex after the integrated circuit device package 120 is attached to the socket 104 as shown in FIG. 1B, i.e., once the pins 105B come into contact with the pads 111B of the package substrate 112. In this example, the pins 105B will scrub/wipe across the pads 111B; however, in other embodiments, where this might not be desired, a compression mount socket can be used with balanced stiffness on the top and bottom sides.

The assembly 100 further includes an integrated circuit device package 120 that includes a package substrate 112, one or more integrated circuit die(s) 114 on the package substrate 112, a thermal interface material (TIM) 116 on the die(s) 114, and a cap 118 enclosing the die(s) 114 and TIM 116 on the top surface of the package substrate 112. The package substrate 112 includes a set of metal contact pads 111A, 111B formed on the backside of the substrate, i.e., on the side opposite from the die(s) 114. The metal pads 111A, 111B allow for electrical connections between the main board 102 and the die(s) 114, via the socket 104, pins 105A (via contact with LM inside the wells) and 105B), and traces within the package substrate 112. The integrated circuit device package 120 also includes an interposer 110 coupled to the substrate 112 on a side opposite the die(s) 114. The interposer 110 is a housing that includes a layer 107 with openings 108, 109 defined therein. The openings 108 are defined around the metal contact pads 111A, and define LM wells (in which a LM comprising Gallium (e.g., a Gallium-based LM alloy), resides as shown). The openings 109 are defined around the metal contact pads 111B and act as openings through which the pins 105B are aligned with and connect to the pads 111B of the package substrate 112. The interposer 110 also includes a barrier 106 to prevent the LM from leaving the LM wells.

As used herein, an opening being “defined around” a metal contact pad (or other type of conductive contact) may refer to the opening's defining structures being formed adjacent to the pad such that the conductive contact is accessible via the opening. This can include the structures of the opening surrounding all or a portion of the conductive contact. For instance, in the example shown, the walls of the openings 108 are defined around the pads 111A such that the pads 111A would be accessible from within the wells 108, e.g., LM within the openings 108 can be in physical contact with the pads 111. Likewise, the walls of the openings 109 are defined around the pads 111B such that the pads 111B would be accessible from within the opening 109. In some embodiments, the openings may be defined around the pads such that the entire pad is accessible from within the opening (e.g., a cross-sectional area of the pad is smaller or equal to the cross-sectional area of the opening), while in other embodiments, the openings may be defined around the pads such that only a portion of the pad is accessible from within the opening (e.g., a cross-sectional area of the pad is larger than the cross-sectional area of the opening).

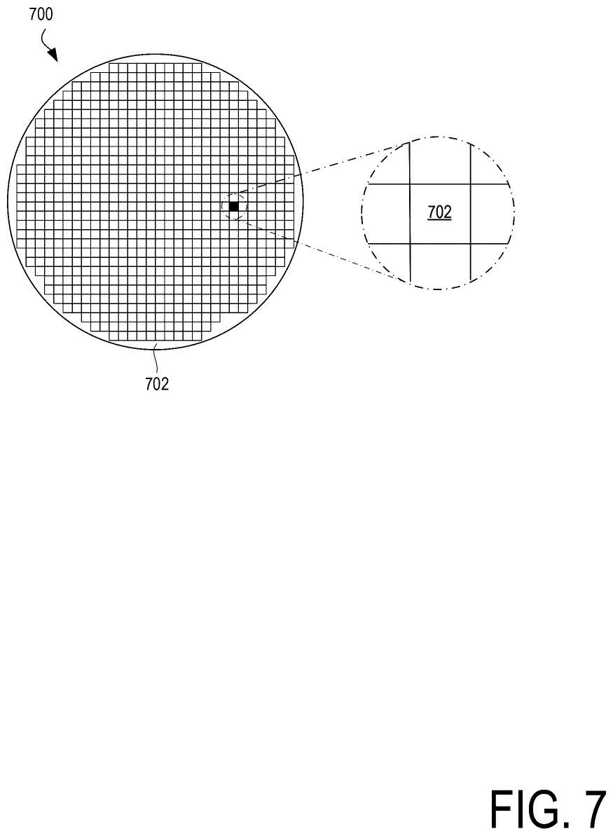

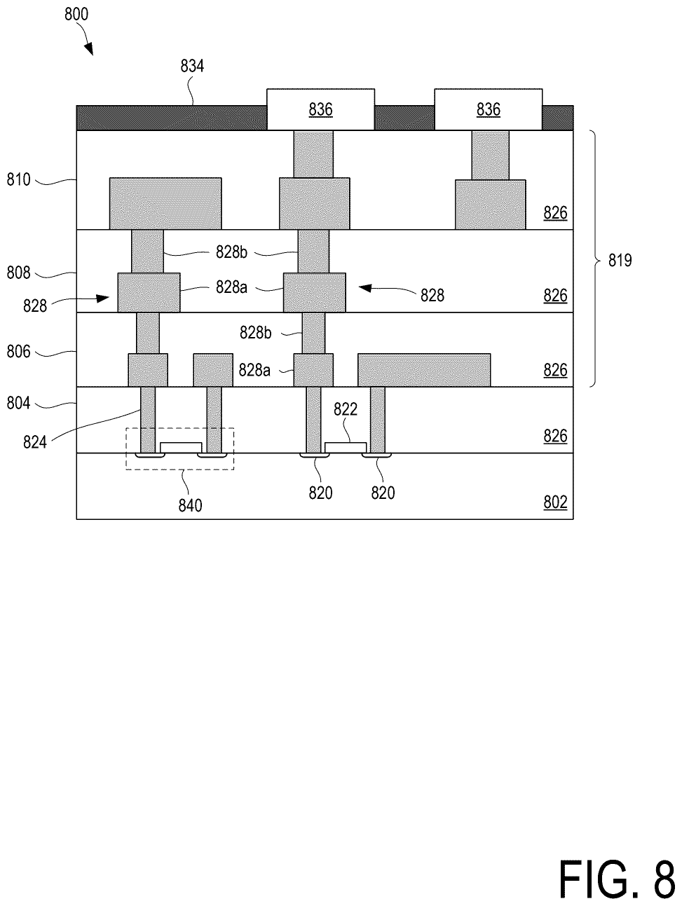

The die(s) 114 may be a packaged or unpacked integrated circuit product that includes one or more integrated circuit dies (e.g., the die 702 of FIG. 7, the integrated circuit device 800 of FIG. 8) and/or one or more other suitable components. The die(s) 114 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the die(s) 114 can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the die(s) 114 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof. The TIM 116 may be any suitable material for providing thermal conduction between the die(s) 114 and the cap 118 (e.g., for heat dissipation).

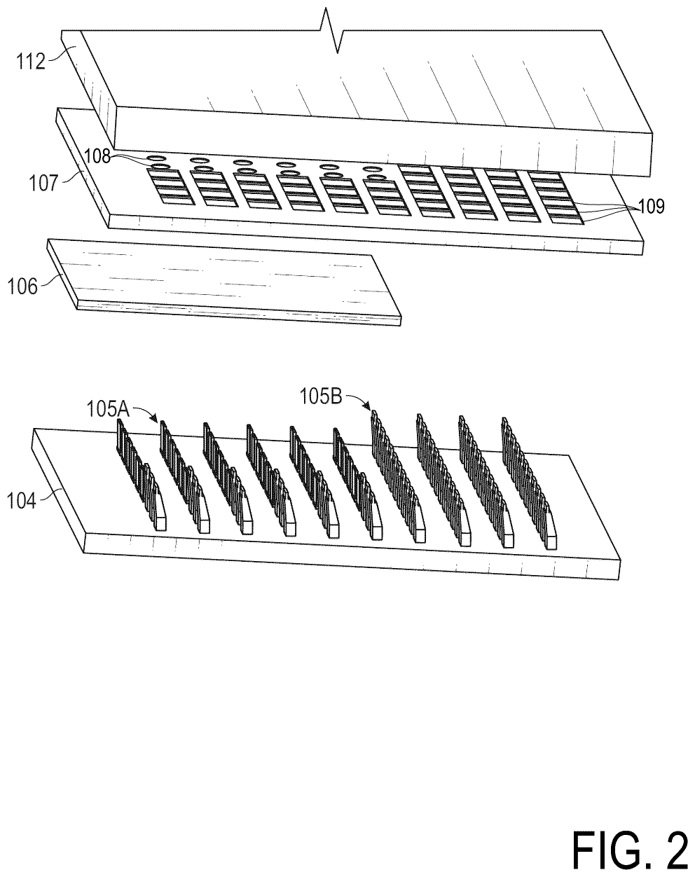

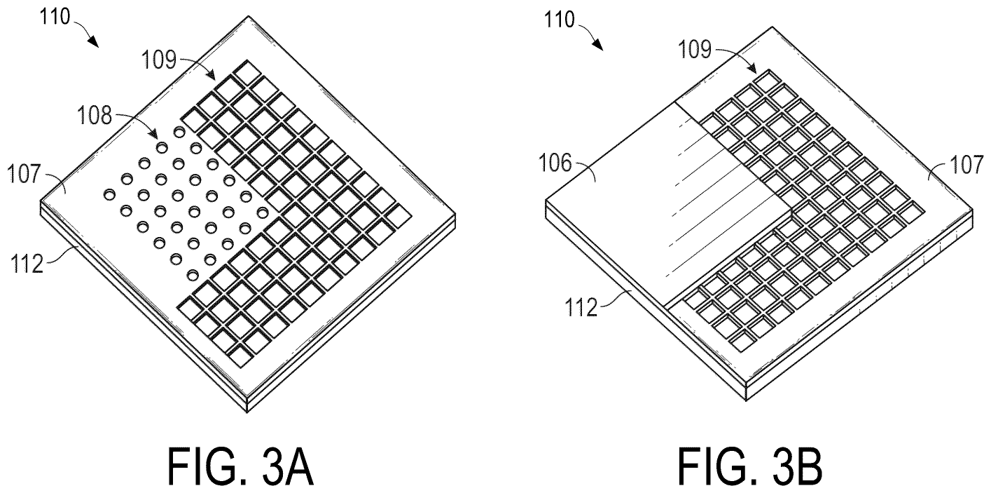

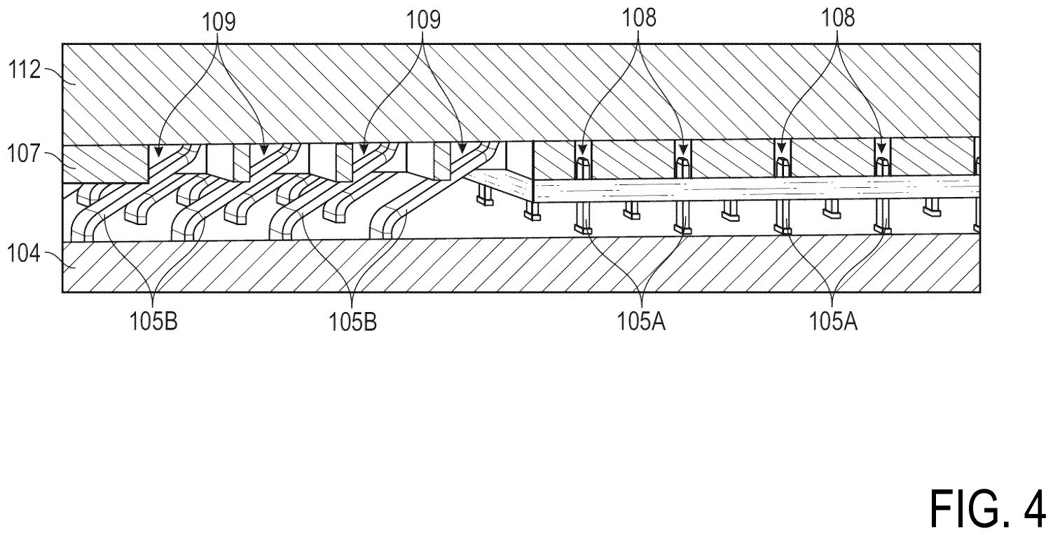

FIGS. 2-4 illustrate various views of the hybrid interconnect of FIGS. 1A-1B. In particular, FIG. 2 illustrates an exploded view FIGS. 3A-3B illustrate perspective views of the interposer 110, and FIG. 4 illustrates a cross-sectional view of the hybrid interconnect (when attached as shown in FIG. 1B). As shown in these various views of the hybrid interconnect, the openings 109 for the LGA connections are relatively larger than the openings 108 to allows for the LGA-compatible pins 105B to pass through them. In addition, as shown, the barrier 106 (which may be a self-sealing material) only the LM-based interconnect area, i.e., the area over the openings 108.

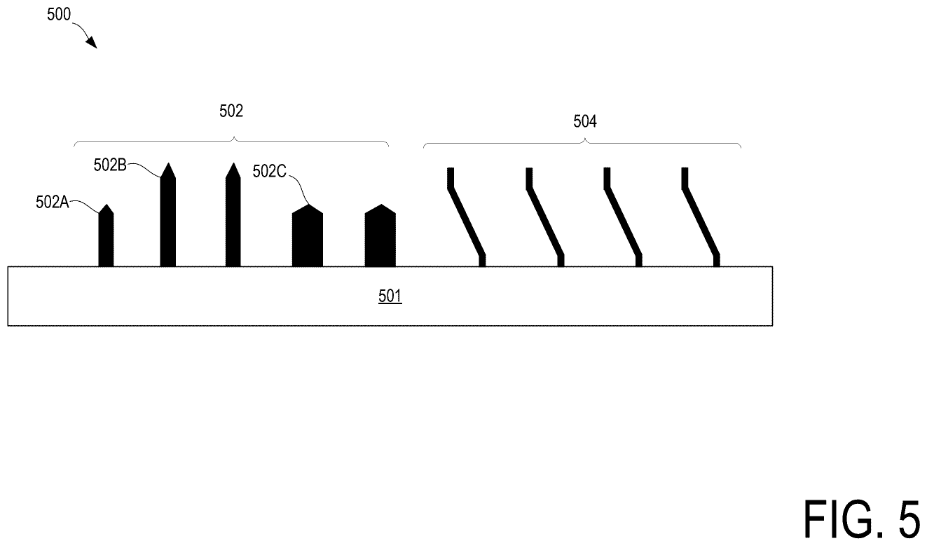

FIG. 5 illustrates an example hybrid socket 500 with varying LM pin dimensions for use with a hybrid LGA-LM interconnect, such as the one shown in FIGS. 1A-1B. As previously discussed, LM-based interconnects are incredibly compliant and their measured resistance is primarily due to bulk conduction. This allows for the ability to use different shapes, thicknesses, heights, etc. for LM-based pins. In the example shown, the socket 500 includes LM-based pins 502 and LGA-based pins 504 extending from a socket body 501, similar to the example socket described above. However, in the example shown in FIG. 5, the LM-based pins 502 includes pins of different cross-sectional dimensions or thicknesses and different heights. For instance, the pins 502A are relatively thin with a low relative height, while the pins 502B have the same cross-sectional dimensions but are taller. In addition, the pins 502C are of the same height as the pins 502A, but have a larger cross-sectional dimension/thickness.

Consider the example of a 100 μm diameter LM-based pin with a height of 100 μm. Such a pin would carry a resistance of approximately 0.6 mOhm. If there is a desire to reduce the bulk resistance, e.g., for power delivery, the pin diameter can be easily extended to 200 μm (e.g., pins 502C), which would reduce the resistance by approximately 4×. However, increasing the diameter in all the pins could run the risk of interaction with the sides of the LM wells and might not be ideal from a signal integrity standpoint. Accordingly, only certain of the pins 502 across the array can be designed with a larger diameter to help optimize the performance for power delivery or signal integrity, and avoiding issues of fit/well wall interaction. As another example, to reduce the risk of ESD when an integrated circuit device package is first inserted into the socket, it may be ideal to have ground pins first come in contact with the LM. This can be achieved by having taller pins (e.g., pins 502B) for ground signals that would come into contact with the LM before the other pins of the socket.

As previously mentioned, one potential drawback of a LM-only interconnect is the need for extraction force to remove a package from a socket. In LM-based sockets, pins may require, e.g., approximately 5 gf/pin to cut through a barrier layer (e.g., 106) for the LM wells. After initial insertion, the force reduces to, e.g., approximately 2 gf/pin. During extraction, the package has to be extracted with a force to overcome the retention force of the barrier layer. For a 4000 pin socket, for example, this force could be upwards of approximately 20 lbf, as an example. To overcome this, current designs may use ejection springs that require extra space and add extra cost to the design. However, if some of the contacts within an array are spring-based (such as in LGA or compression mount technology (CMT) technologies), they are preloaded when compressed, i.e., exert a force back onto the package when the package is attached to the socket. With a hybrid socket, the insertion force is much lower than the purely spring-based design, as the socket includes LM-based pins that don't require much force, but the retention force of the LM-based portion can be overcome by the inherent preload of the spring-based portion of the socket.

Although the previous description relates to an LGA-LM hybrid socket interconnect, aspects of the present disclosure can be extended to other hybrid interconnects with at least a portion of the interconnect being LM. For example, some embodiments may include a hybrid pin grid array (PGA)-LM socket interconnect, while other may include a hybrid CMT-LM interconnect. Other embodiments still can include any combination of different types of interconnects, e.g., a hybrid LGA-PGA-LM interconnect that can incorporate advantageous aspects of each different type of interconnect.

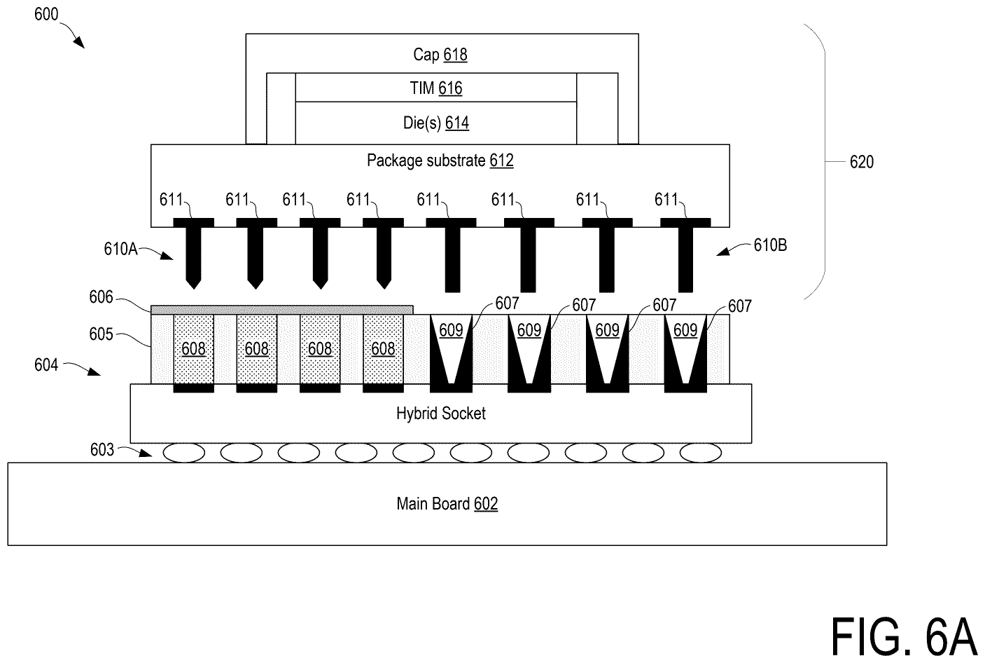

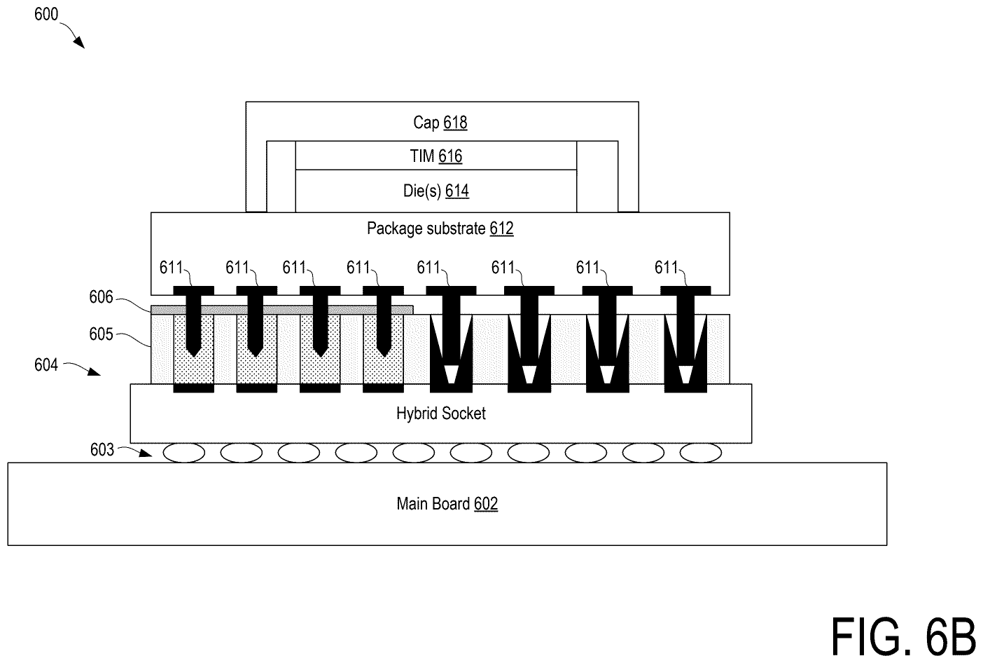

FIGS. 6A-6B illustrate an example integrated circuit device assembly 600 that utilizes a hybrid PGA-LM socket interconnect in accordance with embodiments of the present disclosure. In the example shown, the assembly 600 includes a main board 602, which may be the same as or similar to the main board 102 of FIGS. 1A-1B. The assembly 600 also includes a hybrid socket 604 that includes a layer 605 with openings 608, 609 therein. The openings 608 define LM wells (in which LM, e.g., a Ga-based LM, resides as shown) and the openings 609 with conductive contacts therein to interface with the pins 605B when inserted into the openings 609. The socket 604 also includes a barrier 606 to prevent the LM from leaving the LM wells. The socket 604 is coupled to the main board 602 via solder bumps 603. The bumps 603 may be formed using Tin or any other suitable solder bump material. In some embodiments, the socket 604 may be coupled to the main board 602 via other mechanisms.

The assembly 600 further includes an integrated circuit device package 620 to attach to the socket 604. The package 620 includes a package substrate 612, one or more integrated circuit die(s) 614 on the package substrate 612, a thermal interface material (TIM) 616 on the die(s) 614, and a cap 618 enclosing the die(s) 614 and TIM 616 on the top surface of the package substrate 612. The integrated circuit device package 120 also includes metal contact pads 611 formed on the backside of the substrate, i.e., on the side opposite from the die(s) 614, and also includes a set of LM-compatible pins 610A in connection with a first set of pads 611 and a set of PGA-compatible pins 610B in connection with a second of pads 611.

The LM-compatible pins 610A include sharp ends and enable an electrical connection between the main board 602 and the die(s) 614 (through the LM in wells of the socket 604, pads 611, and conductive paths in the package substrate 612). The LM-compatible pins 610A extend into the LM wells of the socket 604, and accordingly cause the pads 611 to be in electrical contact with the socket 604 and the main board 602. The PGA-compatible pins 610B extend into the openings 609 and become in contact with the contacts 607 inside of the openings 609 when the integrated circuit device package 620 is attached to the socket 604 as shown in FIG. 6B.

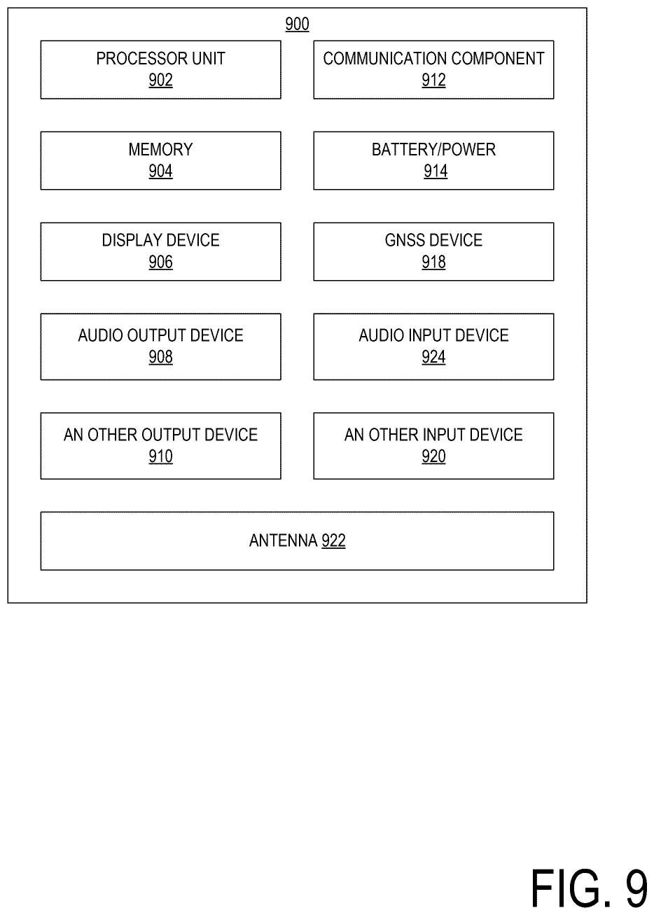

FIG. 7 is a top view of a wafer 700 and dies 702 that may incorporate any of the embodiments disclosed herein. The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 902 of FIG. 9) or other logic that is configured to store information in the memory devices or execute instructions stored in the memory array.

FIG. 8 is a cross-sectional side view of an integrated circuit device 800 that may be included in any of the embodiments disclosed herein. One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 8, a transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page from the perspective of FIG. 8. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the lines 828 of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker that the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board or a package substrate, e.g., 112). The integrated circuit device 800 may include additional or alternate structures to route the electrical signals from the interconnect layers 806-810; for example, the conductive contacts 836 may include other analogous features (e.g., posts) that route the electrical signals to external components.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. In some embodiments, TSVs extending through the substrate can be used for routing power and ground signals from conductive contacts on the opposite side of the integrated circuit device 800 from the conductive contacts 836 to the transistors 840 and any other components integrated into the die 800, and the metallization stack 819 can be used to route I/O signals from the conductive contacts 836 to transistors 840 and any other components integrated into the die 800.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 9 is a block diagram of an example electrical device 900 that may include one or more of the embodiments disclosed herein. For example, any suitable ones of the components of the electrical device 900 may include one or more of assemblies 100, integrated circuit devices 800, or integrated circuit dies 702 disclosed herein. A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards mainboards, or system boards. In some embodiments, one or more of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the processor unit 902. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 900 can comprise one or more processor units 902 that are heterogeneous or asymmetric to another processor unit 902 in the electrical device 900. There can be a variety of differences between the processing units 902 in a system in terms of a spectrum of metrics of merit including architectural, microarchitectural, thermal, power consumption characteristics, and the like. These differences can effectively manifest themselves as asymmetry and heterogeneity among the processor units 902 in the electrical device 900.

In some embodiments, the electrical device 900 may include a communication component 912 (e.g., one or more communication components). For example, the communication component 912 can manage wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include an antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). As noted above, the communication component 912 may include multiple communication components. For instance, a first communication component 912 may be dedicated to shorter-range wireless communications such as Wi-Fi or Bluetooth, and a second communication component 912 may be dedicated to longer-range wireless communications such as global positioning system (GPS), EDGE, GPRS, CDMA, WiMAX, LTE, EV-DO, or others. In some embodiments, a first communication component 912 may be dedicated to wireless communications, and a second communication component 912 may be dedicated to wired communications.

The electrical device 900 may include battery/power supply circuitry 914. The battery/power supply circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System (GNSS) device 918 (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include another output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include another input device 920 (or corresponding interface circuitry, as discussed above). Examples of the other input device 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an apparatus comprising: a substrate comprising conductive contacts on a first side of the substrate; a layer on the first side of the substrate defining a first set of openings around a first subset of the conductive contacts and a second set of openings around a second subset of the conductive contacts; and Gallium-based liquid metal in each of the first set of openings.

Example 2 includes the subject matter of Example 1, wherein a cross-sectional dimension of the first set of openings is less than a cross-sectional dimension of the second set of openings.

Example 3 includes the subject matter of Example 1 or 2, further comprising an integrated circuit device coupled to a second side of the substrate opposite the first side.

Example 4 includes the subject matter of Example 3, further comprising: a circuit board; and a socket coupled to the circuit board, the socket comprising metal pins extending from a side of the socket opposite the circuit board, the metal pins comprising a first subset of pins in contact with the Gallium-based liquid metal and a second subset of pins in contact with second subset of the conductive contacts of the substrate.

Example 5 includes the subject matter of Example 1 or 2, further comprising a circuit board coupled to the substrate on a second side opposite the first side.

Example 6 includes the subject matter of Example 5, further comprising: an integrated circuit device package comprising an integrated circuit die coupled to a package substrate, the package substrate comprising conductive contacts on a side opposite the integrated circuit die; first pins connected to a first subset of the conductive contacts of the substrate, wherein the first pins are in contact with the liquid metal in the first set of the openings; second pins connected to a second subset of the conductive contacts of the substrate, wherein the second pins are in contact with conductive contacts inside the second set of the openings.

Example 7 includes the subject matter of any one of Examples 1-6, wherein the apparatus does not comprise Gallium-based liquid metal in any of the second set of openings.

Example 8 is a system comprising: a circuit board; a socket coupled to the circuit board, the socket comprising pins extending from the socket in a direction opposite the circuit board; and an integrated circuit device assembly coupled to the socket, the integrated circuit device assembly comprising: a substrate comprising conductive contacts on a first side of the substrate; an integrated circuit die coupled to a second side of the substrate opposite the first side; an interposer coupled to the first side of the substrate, the interposer defining first openings around a first subset of the conductive contacts of the substrate and defining second openings around a second subset of the conductive contacts of the substrate; and Gallium-based liquid metal in the first openings; wherein a first subset of the pins of the socket are in contact with the liquid metal in the first openings of the interposer and a second subset of the pins of the socket are inside the second openings and in contact with the second subset of conductive contacts of the substrate.

Example 9 includes the subject matter of Example 8, wherein the first subset of pins comprises a first subset having a first height and second subset having a second height greater than the first height.

Example 10 includes the subject matter of Example 9, wherein the system comprises power supply circuitry and the second subset of the first subset of pins are connected to a ground signal of the power supply circuitry.

Example 11 includes the subject matter of any one of Examples 8-10, wherein the first subset of pins comprises a first subset having a first cross-sectional dimension and a second subset having a second cross-sectional dimension greater than the first cross-sectional dimension.

Example 12 includes the subject matter of Example 11, wherein the system comprises power supply circuitry and the second subset of the first subset of pins are connected to a voltage signal of the power supply circuitry.

Example 13 includes the subject matter of any one of Examples 8-12, wherein the second subset of pins exert a force onto the substrate.

Example 14 is a system comprising: a circuit board; a socket coupled to the circuit board; an integrated circuit device assembly coupled to the socket, the integrated circuit device assembly comprising: a substrate comprising conductive contacts on a first side of the substrate; and an integrated circuit die coupled to a second side of the substrate opposite the first side; first means for coupling the integrated circuit device assembly to the socket, the first means comprising liquid metal-based connections between the integrated circuit device assembly and the socket; and second means for coupling the integrated circuit device assembly to the socket, the second means comprising no liquid metal-based connections between the integrated circuit device assembly and the socket.

Example 15 includes the subject matter of Example 14, wherein the first means comprises a first subset of pins having a first height and second subset of pins having a second height greater than the first height.

Example 16 includes the subject matter of Example 15, wherein the system comprises power supply circuitry and the second subset of pins are connected to a ground signal of the power supply circuitry.

Example 17 includes the subject matter of any one of Examples 14-16, wherein the first means comprises a first subset of pins having a first cross-sectional dimension and a second subset of pins having a second cross-sectional dimension greater than the first cross-sectional dimension.

Example 18 includes the subject matter of Example 17, wherein the system comprises power supply circuitry and the second subset of pins are connected to a voltage signal of the power supply circuitry.

Example 19 includes the subject matter of any one of Examples 14-18, wherein the second means comprises land grid array (LGA)-based connections.

Example 20 includes the subject matter of any one of Examples 14-18, wherein the second means comprises pin grid array (PGA)-based connections.

Example 21 includes the subject matter of any one of Examples 14-18, wherein the second means comprises compression mount technology (CMT)-based connections.

Example 22 is a system comprising: a circuit board; a socket coupled to the circuit board, the socket comprising a set of openings defined therein, a first subset of the openings comprising a Gallium-based liquid metal therein and a second subset of the openings comprising conductive contacts on an inner surface; an integrated circuit device assembly coupled to the socket, the integrated circuit device assembly comprising: a substrate comprising conductive contacts on a first side of the substrate; an integrated circuit die coupled to a second side of the substrate opposite the first side; first pins connected to a first subset of the conductive contacts of the substrate, wherein the first pins are in contact with the liquid metal in the first subset of the openings of the socket; second pins connected to a second subset of the conductive contacts of the substrate, wherein the second pins are in contact with the conductive contacts inside the second subset of the openings of the socket.

Example 23 includes the subject matter of Example 22, wherein the first pins comprise a first subset having a first height and second subset having a second height greater than the first height.

Example 24 includes the subject matter of Example 23, wherein the system comprises power supply circuitry and the second subset of the first pins are connected to a ground signal of the power supply circuitry.

Example 25 includes the subject matter of any one of Examples 22-24, wherein the first pins comprise a first subset having a first cross-sectional dimension and a second subset having a second cross-sectional dimension greater than the first cross-sectional dimension.

Example 26 includes the subject matter of Example 25, wherein the system comprises power supply circuitry and the second subset of the first pins are connected to a voltage signal of the power supply circuitry.

Example 27 is apparatus comprising: a first substrate comprising conductive contacts on a first side of the substrate; a housing coupled to the first side of the substrate, the housing comprising: first openings defined around a first subset of the conductive contacts of the first substrate; liquid metal in the first openings and in contact with the first subset of the conductive contacts; and second openings defined around a second subset of the conductive contacts of the first substrate; and a second substrate comprising: first pins in contact with the liquid metal in the first openings; and second pins in contact with second subset of the conductive contacts.

Example 28 includes the subject matter of Example 27, wherein the apparatus does not comprise liquid metal in any of the second openings.

Example 29 includes the subject matter of Example 27 or 28, further comprising a barrier layer enclosing the liquid metal in the first openings.

Example 30 includes the subject matter of any one of Examples 27-29, wherein a cross-sectional dimension of the first openings is less than a cross-sectional dimension of the second openings.

Example 31 includes the subject matter of any one of Examples 27-30, further comprising an integrated circuit device coupled to a second side of the first substrate opposite the first side and a circuit board coupled to the second substrate.

Example 32 includes the subject matter of any one of Examples 27-30, further comprising a circuit board coupled to the first substrate on a second side opposite the first side and an integrated circuit die coupled to the second substrate.

Example 33 includes the subject matter of any one of Examples 27-32, wherein the first pins comprise a first subset having a first height and second subset having a second height greater than the first height.

Example 34 includes the subject matter of any one of Examples 27-33, wherein the first pins comprise a first subset having a first cross-sectional dimension and a second subset having a second cross-sectional dimension greater than the first cross-sectional dimension.

Example 35 includes the subject matter of any one of Examples 27-34, wherein the second pins exert a force onto the first substrate.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

Further, concepts described herein are illustrated by way of example and not by way of limitation in the accompanying Figures. For simplicity and clarity of illustration, elements illustrated in the Figures might not be necessarily drawn to scale. Where considered appropriate, reference labels may have been repeated between certain Figures to indicate corresponding or analogous elements.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An apparatus comprising:
a first substrate comprising conductive contacts on a first side of the substrate;
a housing coupled to the first side of the substrate, the housing comprising:
first openings defined around a first subset of the conductive contacts of the first substrate;
liquid metal in the first openings and in contact with the first subset of the conductive contacts; and
second openings defined around a second subset of the conductive contacts of the first substrate; and
a second substrate comprising:
first pins in contact with the liquid metal in the first openings; and
second pins in contact with second subset of the conductive contacts.

2. The apparatus of claim 1, wherein the apparatus does not comprise liquid metal in any of the second openings.

3. The apparatus of claim 1, further comprising a barrier layer enclosing the liquid metal in the first openings.

4. The apparatus of claim 1, wherein a cross-sectional dimension of the first openings is less than a cross-sectional dimension of the second openings.

5. The apparatus of claim 1, further comprising an integrated circuit device coupled to a second side of the first substrate opposite the first side and a circuit board coupled to the second substrate.

6. The apparatus of claim 1, further comprising a circuit board coupled to the first substrate on a second side opposite the first side and an integrated circuit die coupled to the second substrate.

7. The apparatus of claim 1, wherein the first pins comprise a first subset having a first height and second subset having a second height greater than the first height.

8. The apparatus of claim 1, wherein the first pins comprise a first subset having a first cross-sectional dimension and a second subset having a second cross-sectional dimension greater than the first cross-sectional dimension.

9. The apparatus of claim 1, wherein the second pins exert a force onto the first substrate.

10. A system comprising:
a circuit board;
a socket coupled to the circuit board, the socket comprising pins extending from the socket in a direction opposite the circuit board; and
an integrated circuit device assembly coupled to the socket, the integrated circuit device assembly comprising:
a substrate comprising conductive contacts on a first side of the substrate;
an integrated circuit die coupled to a second side of the substrate opposite the first side;
an interposer coupled to the first side of the substrate, the interposer defining first openings around a first subset of the conductive contacts of the substrate and defining second openings around a second subset of the conductive contacts of the substrate; and
liquid metal in the first openings;
wherein a first subset of the pins of the socket are in contact with the liquid metal in the first openings of the interposer and a second subset of the pins of the socket are inside the second openings and in contact with the second subset of conductive contacts of the substrate.

11. The system of claim 10, wherein the first subset of pins comprises a first subset having a first height and second subset having a second height greater than the first height.

12. The system of claim 11, wherein the system comprises power supply circuitry and the second subset of the first subset of pins are connected to a ground signal of the power supply circuitry.

13. The system of claim 10, wherein the first subset of pins comprises a first subset having a first cross-sectional dimension and a second subset having a second cross-sectional dimension greater than the first cross-sectional dimension.

14. The system of claim 13, wherein the system comprises power supply circuitry and the second subset of the first subset of pins are connected to a voltage signal of the power supply circuitry.

15. The system of claim 10, wherein the second subset of pins exert a force onto the substrate.

16. A system comprising:
a circuit board;
a socket coupled to the circuit board, the socket comprising a set of openings defined therein, a first subset of the openings comprising a liquid metal therein and a second subset of the openings comprising conductive contacts on an inner surface;
an integrated circuit device assembly coupled to the socket, the integrated circuit device assembly comprising:
a substrate comprising conductive contacts on a first side of the substrate;
an integrated circuit die coupled to a second side of the substrate opposite the first side;
first pins connected to a first subset of the conductive contacts of the substrate, wherein the first pins are in contact with the liquid metal in the first subset of the openings of the socket;
second pins connected to a second subset of the conductive contacts of the substrate, wherein the second pins are in contact with the conductive contacts inside the second subset of the openings of the socket.

17. The system of claim 16, wherein the first pins comprise a first subset having a first height and second subset having a second height greater than the first height.

18. The system of claim 17, wherein the system comprises power supply circuitry and the second subset of the first pins are connected to a ground signal of the power supply circuitry.

19. The system of claim 16, wherein the first pins comprise a first subset having a first cross-sectional dimension and a second subset having a second cross-sectional dimension greater than the first cross-sectional dimension.

20. The system of claim 19, wherein the system comprises power supply circuitry and the second subset of the first pins are connected to a voltage signal of the power supply circuitry.
